(19) United States
(12) Patent Application Publication
(10) Pub. No.: US 2024/0371836 A1
(43) Pub. Date: Nov. 7, 2024

(54) PIXEL ASSEMBLY AND DISPLAY DEVICE

(71) Applicant: KYOCERA Corporation, Kyoto-shi, Kyoto (JP)

(72) Inventor: Yohei SATO, Muko-shi, Kyoto (JP)

(21) Appl. No.: 18/292,893

(22) PCT Filed: Jul. 15, 2022
(86) PCT No.: PCT/JP2022/027935

§ 371 Date: Jan. 26, 2024

(30) Foreign Application Priority Data
Jul. 30, 2021 (JP) 2021-125782

(51) Int. Cl. H01L 25/075

(52) U.S. Cl. CPC H01L 25/0753

(57) ABSTRACT

A pixel assembly includes an insulating substrate including a first surface and a second surface on an opposite side to the first surface, a drive transistor located in the insulating substrate or on the first surface and including a source electrode and a drain electrode, a power feeder connectable to an external power supply, a connection conductor layer located on the insulating substrate and connecting the source electrode to the power feeder, and a light emitter located on the second surface and electrically connected to the drain electrode. The connection conductor layer includes a surrounding portion surrounding the light emitter in a plan view on the second surface.

### TECHNICAL FIELD

The present disclosure relates to a pixel assembly and a display device including the pixel assembly.

### BACKGROUND OF INVENTION

A known display device is described in, for example, Patent Literature 1.

### CITATION LIST

### Patent Literature

Patent Literature 1: Japanese Unexamined Patent Application Publication No. 2008-65200

### SUMMARY

In an aspect of the present disclosure, a pixel assembly includes an insulating substrate including a first surface and a second surface on an opposite side to the first surface, a drive transistor located in the insulating substrate or on the first surface and including a source electrode and a drain electrode, a power feeder connectable to an external power supply, a connection conductor layer located on the insulating substrate and connecting the source electrode to the power feeder, and a light emitter located on the second surface and electrically connected to the drain electrode. The connection conductor layer includes a surrounding portion surrounding the light emitter in a plan view on the second surface.

In an aspect of the present disclosure, a pixel assembly includes an insulating substrate including a first surface and a second surface on an opposite side to the first surface, a drive transistor located in the insulating substrate or on the first surface and including a source electrode and a drain electrode, a power feeder connectable to an external power supply, a connection conductor layer located on the insulating substrate and connecting the source electrode to the power feeder, and a light emitter located on the second surface and electrically connected to the drain electrode. The connection conductor layer includes a planar portion on the second surface.

In an aspect of the present disclosure, a pixel assembly includes an insulating substrate including a first surface and a second surface on an opposite side to the first surface and including a recess on the second surface, a drive transistor located in the insulating substrate or on the first surface and including a source electrode and a drain electrode, a power feeder connectable to an external power supply, a connection conductor layer located on the insulating substrate and connecting the source electrode to the power feeder, and a light emitter located in the recess and electrically connected to the drain electrode. The connection conductor layer includes at least one of a surrounding portion surrounding the light emitter in a plan view or a planar portion on the second surface.

In an aspect of the present disclosure, a display device includes the pixel assembly according to any one of the above aspects, and a substrate including one main surface receiving the pixel assembly and another main surface receiving a drive that drives the light emitter. The other main surface is opposite to the one main surface.

### BRIEF DESCRIPTION OF THE DRAWINGS

The objects, features, and advantages of the present disclosure will become more apparent from the following detailed description and the drawings.

FIG. 1 is a plan view of a pixel assembly according to an embodiment of the present disclosure.

FIG. 2 is a cross-sectional view taken along line A1-A2 in FIG. 1.

FIG. 3 is a circuit diagram of the pixel assembly according to the embodiment of the present disclosure.

FIG. 4 is a circuit diagram of the pixel assembly according to the embodiment of the present disclosure.

FIG. 5A is a plan view of a pixel assembly according to another embodiment of the present disclosure.

FIG. 5B is a plan view of a pixel assembly according to the other embodiment of the present disclosure.

FIG. 6 is a cross-sectional view of a pixel assembly according to the other embodiment of the present disclosure.

FIG. 7 is a plan view of a pixel assembly according to still another embodiment of the present disclosure.

FIG. 8 is a cross-sectional view taken along line B1-B2 in FIG. 7.

FIG. 9 is a cross-sectional view of a display device according to an embodiment of the present disclosure.

### DESCRIPTION OF EMBODIMENTS

The structure that forms the basis of a pixel assembly and a display device according to one or more embodiments of the present disclosure will now be described. The display device described in Patent Literature 1 includes a substrate, an insulating layer located on the substrate, drive transistors located between the substrate and the insulating layer, and light emitters located on the insulating layer. Numerous pixel units including light emitters and drive transistors are arranged in a matrix on the substrate. The drive transistors have their source electrodes connected to supply voltage terminals on the substrate with internal wires inside the insulating layer. The internal wires are located inside the insulating layer including various wires of the display device, various via conductors, and other components. In a display device with this structure, the supply voltage fed to the source electrodes of the drive transistors tends to decrease as the distance from the power supply voltage terminal increases in a planar direction along the display surface. This may cause uneven luminance or uneven colors in display images, possibly causing lower image quality.

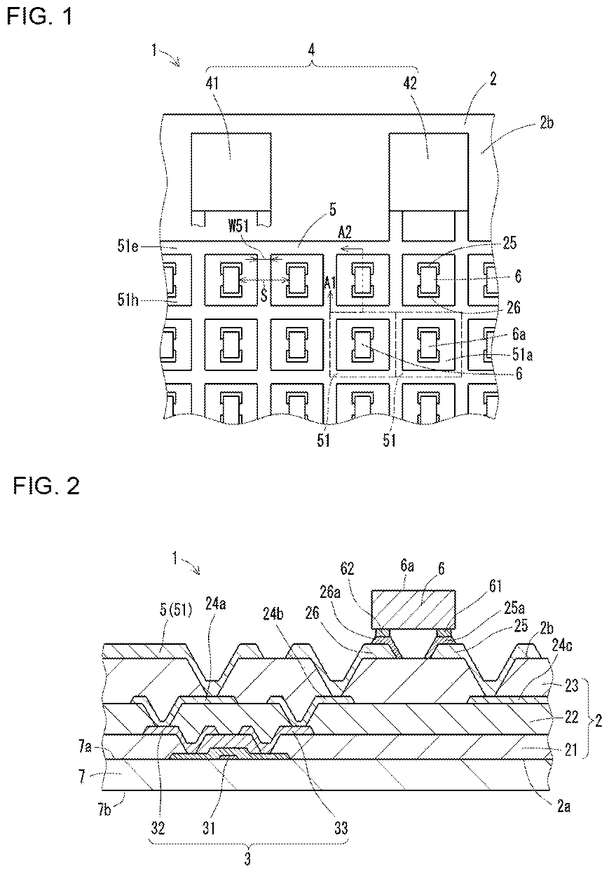

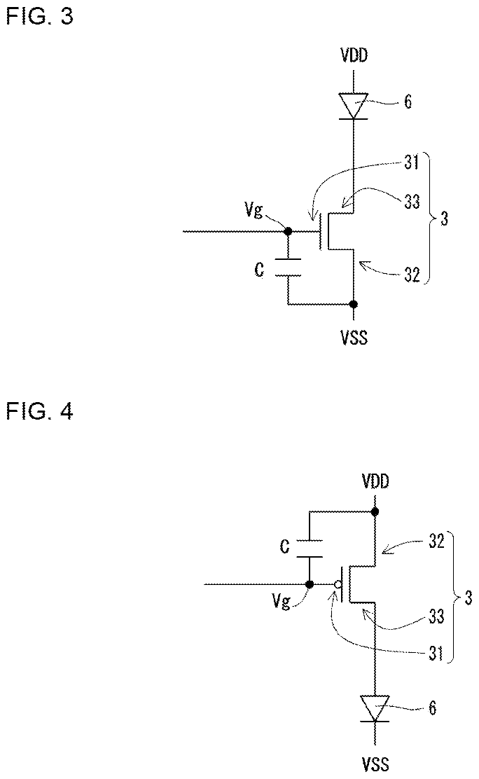

A pixel assembly and a display device according to one or more embodiments of the present disclosure will now be described with reference to the accompanying drawings. Each figure referred to below illustrates main components and other elements of the pixel assembly and the display device according to one or more embodiments of the present disclosure. In an embodiment of the present disclosure, a pixel assembly and a display device may include known components not illustrated in the figures, such as circuit boards, wiring conductors, control ICs, and LSI circuits. The figures referred to below are schematic, and may not be drawn to scale relative to, for example, the actual positions and dimensional ratios of components of the pixel assembly and the display device. FIG. 1 is a plan view of a pixel assembly according to an embodiment of the present disclosure. FIG. 2 is a cross-sectional view taken along line A1-A2 in FIG. 1. FIGS. 3 and 4 are circuit diagrams of the pixel assembly according to the embodiment of the present disclosure. FIG. 3 is a circuit diagram of the pixel assembly with a drive transistor being an n-channel thin-film transistor (TFT). FIG. 4 is a circuit diagram of the pixel assembly with a drive transistor being a p-channel TFT. A pixel assembly with a drive transistor being an n-channel TFT as illustrated in FIG. 3 is described herein, unless otherwise specified.

In the present embodiment, the pixel assembly 1 includes an insulating substrate 2, drive transistors 3, power terminals 4, a connection conductor layer 5, and light emitters 6.

The insulating substrate 2 includes a first surface (one main surface) 2a and a second surface (the other main surface) 2b opposite to the first surface 2a. The insulating substrate 2 may be, for example, a triangular plate, a quadrangular plate such as a square plate or a rectangular plate, a trapezoidal plate, a hexagonal plate, a circular plate, an oval plate, or a plate with any other shape. The insulating substrate 2 may include a single insulating layer, or may include multiple insulating layers stacked on one another. In other words, the insulating substrate 2 may be a stack of insulating layers. In the present embodiment, the insulating substrate 2 includes insulating layers 21, 22, and 23 stacked on one another as illustrated in, for example, FIG. 2. The insulating layers 21, 22, and 23 may include, for example, organic insulating layers of silicon oxide (SiO₂), silicon nitride (Si₃N₄), or other materials, and organic insulating layers of an acrylic resin, a polyimide resin, a polycarbonate resin, or other materials. For example, the insulating layers 21 and 22 in a lower portion (closer to the substrate 7) of the insulating substrate 2 may be inorganic insulating layers, and the insulating layer 23 at the top of the insulating substrate 2 may be an organic insulating layer as a planarization layer thicker than each of the insulating layers 21 and 22. The insulating layers 21, 22, and 23 may be the same as or different from one another in composition, dimensions (thickness), and other features.

The insulating substrate 2 includes internal wires 24a, 24b, and 24c. The internal wires 24a, 24b, and 24c electrically connect the drive transistors 3, the power terminals 4, the connection conductor layer 5, the light emitters 6, and other components with one another. The internal wires 24a, 24b, and 24c may be located between adjacent ones of the insulating layers 21, 22, and 23 as illustrated in, for example, FIG. 2. The internal wires 24a, 24b, and 24c may include, for example, layers of Mo/Al/Mo or MoNd/AlNd/MoNd. The stack of Mo/Al/Mo includes a Mo layer, an Al layer, and a Mo layer in this order. The same applies to other notations.

The insulating substrate 2 includes anode electrode wires 25 and cathode electrode wires 26. Each anode electrode wire 25 electrically connects the internal wire 24c and an anode terminal 61 of the corresponding light emitter 6. Each cathode electrode wire 26 electrically connects the internal wire 24b and a cathode terminal 62 of the corresponding light emitter 6. The anode electrode wires 25 and the cathode electrode wires 26 may be located on the second surface 2b, or between adjacent ones of the insulating layers 21, 22, and 23. Each anode electrode wire 25 may be directly connected to the anode terminal, or may be connected to the anode terminal with a transparent conductive layer 25a in between. Each cathode electrode wire 26 may be directly connected to the cathode terminal, or may be connected to the cathode terminal with a transparent conductive layer 26a in between. In the example in FIG. 2, the anode electrode wire 25 is connected to the anode terminal 61 with the transparent conductive layer 25a in between, and the cathode electrode wire 26 is connected to the cathode terminal 62 with the transparent conductive layer 26a in between. The transparent conductive layers 25a and 26a each may be a transparent conductive layer of, for example, tin oxide (ITO) or indium zinc oxide (IZO).

The pixel assembly 1 may be located on the substrate 7 as illustrated in, for example, FIG. 2. The substrate 7 includes a third surface (one main surface) 7a, a fourth surface (the other main surface) 7b opposite to the third surface 7a, and fifth surfaces 7c (illustrated in FIG. 9) connecting the third surface 7a and the fourth surface 7b. The pixel assembly 1 may be located on the substrate 7 with the first surface 2a of the insulating substrate 2 facing the third surface 7a of the substrate 7.

The substrate 7 may be made of, for example, a glass material, a ceramic material, or a resin material. Examples of the glass material used for the substrate 7 include borosilicate glass, crystallized glass, and quartz. Examples of the ceramic material used for the substrate 7 include alumina (Al₂O₃), zirconia (ZrO₂), silicon nitride (Si₃N₄), silicon carbide (SiC), and aluminum nitride (AlN). Examples of the resin material used for the substrate 7 include an epoxy resin, a polyimide resin, a polyamide resin, an acrylic resin, and a polycarbonate resin.

The substrate 7 may be made of, for example, a metal material, an alloy material, or a semiconductor material. Examples of the metal material used for the substrate 7 include aluminum (Al), magnesium (Mg) (specifically, high-purity magnesium with Mg content of 99.95% or higher), zinc (Zn), tin (Sn), copper (Cu), chromium (Cr), and nickel (Ni).

Examples of the alloy material used for the substrate 7 include duralumin, which is an aluminum alloy containing aluminum as a main component (an Al—Cu alloy, an Al—Cu—Mg alloy, or an Al—Zn—Mg—Cu alloy), a magnesium alloy containing magnesium as a main component (a Mg—Al alloy, a Mg—Zn alloy, or a Mg—Al—Zn alloy), titanium boride, stainless steel, and a Cu—Zn alloy. Examples of the semiconductor material used for the substrate 7 include silicon (Si), germanium (Ge), and gallium arsenide (GaAs).

For the substrate 7 made of a metal material, an alloy material, or a semiconductor material, an insulating layer (not illustrated) of, for example, silicon oxide (SiO₂) or silicon nitride (Si₃N₄) may be located between the drive transistors 3 and the substrate 7.

The drive transistor 3 is located in the insulating substrate 2 or on the first surface 2a of the insulating substrate 2. The drive transistor 3 controls, for example, the light emitting operation (emission or non-emission state and the light intensity) of the light emitter 6. The drive transistor 3 may be, for example, a thin-film transistor (TFT). The drive transistor 3 may include a semiconductor film (also referred to as a channel) of, for example, amorphous silicon (a-Si) or low-temperature polycrystalline silicon (LTPS). The drive transistor 3 may include three terminals, or specifically, a gate electrode 31, a source electrode 32, and a drain electrode 33. The drive transistor 3 switches conduction (on-state) and non-conduction (off-state) between the source electrode 32 and the drain electrode 33 based on the voltage applied to the gate electrode 31.

In the example described below; the drive transistor 3 is a TFT including a semiconductor film (channel), the gate electrode 31, the source electrode 32, and the drain electrode 33. The drive transistor 3 may be an n-channel TFT or a p-channel TFT. The power terminal 4 as a power feeder is connected to an external power supply (not illustrated) that applies a supply voltage to the power terminal 4. The power terminal 4 may be located in the insulating substrate 2 or on the second surface 2b of the insulating substrate 2, or on the third surface 7a of the substrate 7. The power terminal 4 may be located on a peripheral portion of the second surface 2b, or on a peripheral portion of the third surface 7a. The pixel assembly 1 may include multiple power terminals 4. The power terminals 4 may include one or more first power terminals (also referred to as first power feeders) 41 and one or more second power terminals (also referred to as second power feeders) 42. A first power supply voltage VDD is applied to the first power terminals 41. A second power supply voltage VSS lower than the first power supply voltage VDD is applied to the second power terminals 42. The first power supply voltage VDD and the second power supply voltage VSS are predetermined as appropriate for the type of the light emitters 6 and other conditions. The power terminals 4 may include, for example, layers of Al, Al/Ti, Ti/Al/Ti, Mo, Mo/Al/Mo, MoNd/AlNd/MoNd, Cu, Cr, Ni, or Ag.

Each power feeder may not have an island-like shape as in the example of the power terminal 4, but may be an end of wiring, or an end of a through-hole or another feedthrough conductor.

The connection conductor layer 5 connects the source electrode 32 of the drive transistor 3 to the power terminal 4. The connection conductor layer 5 feeds a supply voltage to the source electrode 32 of the drive transistor 3. The connection conductor layer 5 may be located on the second surface 2b, or between adjacent ones of the insulating layers 21, 22, and 23. The connection conductor layer 5 may include a portion on the second surface 2b, and another portion between adjacent ones of the insulating layers 21, 22, and 23. The connection conductor layer 5 may include, for example, layers of Mo/Al/Mo or MoNd/AlNd/MoNd. The connection conductor layer 5 may be a transparent conductive layer of, for example, ITO or IZO.

For the connection conductor layer 5 including a portion on the second surface 2b (surface portion) and an interlayer portion between adjacent ones of the insulating layers 21, 22, and 23, the surface portion may have a larger area than the interlayer portion. This allows the drive circuits for the light emitters 6 to be located between layers of the insulating substrate 2 easily, thus reducing the volume of the insulating substrate 2. In some embodiments, the connection conductor layer 5 may be located on the second surface 2b alone. This allows the drive circuits for the light emitters 6 to be located between layers of the insulating substrate 2 more easily, thus reducing both the volume and the thickness of the insulating substrate 2. This shortens signal paths for the drive circuits and improves electrical connection in the internal wiring. This improves the speed and the reliability of drive circuit operations. For example, the insulating substrate 2 may include fewer insulating layers to reduce the number of connections in the vertical direction through a feedthrough conductor, such as a via hole. More specifically, a through-hole formed by etching for a feedthrough conductor tends to have a smaller diameter in its lower part. This increases the likelihood of connection failure at the lower end of the feedthrough conductor.

The light emitters 6 are located on the second surface 2b of the insulating substrate 2. Each light emitter 6 may be a light-emitting diode (LED) or a self-luminous light emitter such as a semiconductor laser diode (LD). In the present embodiment, the light emitter 6 is an

LED. Each light emitter 6 may be a micro-LED (μLED). In this case, the light emitter 6 may be quadrangular and has each side with a length of about 1 to 100 μm inclusive, or about 5 to 20 μm inclusive as viewed in a direction orthogonal to its light-emitting surface 6a. When the light emitter 6 is a μLED, the first power supply voltage VDD may be, for example, about 10 to 15 V, and the second power supply voltage VSS may be, for example, about 0 to 3 V.

Each light emitter 6 includes two terminals, or specifically, an anode terminal 61 and a cathode terminal 62. As illustrated in, for example, FIG. 2, the anode terminals 61 are electrically connected to the anode electrode wires 25, and the cathode terminals 62 are electrically connected to the cathode electrode wires 26.

The pixel assembly 1 may include multiple light emitters 6 and multiple drive transistors 3 for driving the respective light emitters 6. The light emitters 6 may be arranged in a matrix on the second surface 2b. In the example described below; the pixel assembly 1 includes multiple pixels each including the light emitter 6 and the drive transistor 3 to drive the light emitter 6, unless otherwise specified.

Each pixel in the pixel assembly 1 may include a circuit as illustrated in, for example, FIG. 3 when the drive transistor 3 is an n-channel TFT. FIG. 3 is a circuit diagram of each pixel in the pixel assembly 1. Each pixel includes the drive transistor 3, the light emitter 6, and a capacitor C, as illustrated in, for example, FIG. 3. The drive transistor 3 includes the source electrode 32 connected to the second power terminal 42 (illustrated in FIG. 1) to which the second power supply voltage VSS is applied. The capacitor C maintains the level (voltage) of a light emission control signal that is written into a pixel node Vg from an emission control signal line (not illustrated). Each pixel may include a TFT as a switching element that controls writing of the level (voltage) of the emission control signal into the pixel node Vg. The drive transistor 3 drives the light emitter 6 with a current using the potential difference between the first power supply voltage VDD and the second power supply voltage VSS determined based on the level (voltage) of the emission control signal. Thus, fluctuations in the second power supply voltage VSS fed from the power terminal 4 to the source electrode 32 can cause uneven color or uneven luminance in display images.

Each pixel in the pixel assembly 1 may include a circuit as illustrated in, for example, FIG. 4 when the drive transistor 3 is a p-channel TFT. The drive transistor 3 includes the source electrode 32 connected to the first power terminal 41 (illustrated in FIG. 1) to which the first power supply voltage VDD is applied. The drive transistor 3 drives the light emitter 6 in the same or similar manner as when the drive transistor 3 is an n-channel TFT. When the drive transistor 3 is a p-channel TFT, fluctuations in the first power supply voltage VDD fed from the power terminal 4 to the source electrode 32 can cause uneven color or uneven luminance in display images.

In the pixel assembly 1 according to the present embodiment, the connection conductor layer 5 connecting the source electrodes 32 of the drive transistors 3 to the power terminals 4 includes surrounding portions 51 located on the second surface 2b of the insulating substrate 2. The surrounding portions 51 surround the light emitters 6 in a plan view as illustrated in, for example, FIG. 1. The connection conductor layer 5 including the surrounding portions 51 has a larger area in a plan view; and a larger cross-sectional area accordingly. This reduces electrical resistance between the power terminals 4 and the source electrodes 32. In the pixel assembly 1, a supply voltage fed from the power terminal 4 to the source electrode 32 is less likely to drop as the distance from the power terminal 4 increases in a planar direction along the second surface 2b. The pixel assembly 1 thus reduces uneven color or uneven luminance in display images.

When the drive transistor 3 is an n-channel TFT, the power supply voltage of the drive that drives the pixel assembly 1 can be lower than the first power supply voltage VDD of the light emitter 6, allowing the drive to use a smaller area and consume less power.

In the pixel assembly 1 including multiple light emitters 6, the surrounding portions 51 may be a mesh conductive layer including conductor layer strips surrounding the multiple light emitters 6 individually. Each surrounding portion 51 may surround a predetermined number of (e.g., three) light emitters 6 together. The predetermined number of light emitters 6 may include, for example, a light emitter that emits red light, a light emitter that emits green light, and a light emitter that emits blue light. In other words, as illustrated in FIG. 1, the pixel assembly 1 may include multiple light emitters 6 and multiple surrounding portions 51 that surround the light emitters 6 individually, with the surrounding portions 51 connected to one another. This structure further increases the area of the connection conductor layer 5, thus further reducing a drop in the supply voltage fed to the source electrodes 32 of the drive transistors 3.

The surrounding portions 51 in the connection conductor layer 5 may have a width W51 of about 20 to 50% of a space S between adjacent light emitters 6 in a plan view. This effectively reduces electrical resistance between the power terminals 4 and the source electrodes 32, thus effectively reducing a drop in the supply voltage fed from the power terminals 4 to the source electrodes 32. This also reduces short-circuiting between the surrounding portions 51 and the anode terminals 61 or between the surrounding portions 51 and cathode terminals 62 in the manufacturing process of the pixel assembly 1. When the space between the light emitters 6 adjacent in the horizontal direction (right-left direction in FIG. 1) of the pixel assembly 1 differ from that in the vertical direction (up-down direction in FIG. 1), the space S may be the smaller of the horizontal space and the vertical space. In some embodiments, the surrounding portion 51 may have the widths W51 that are defined separately for the spaces in the horizontal direction and the vertical direction of the pixel assembly 1.

The portions of the second surface 2b (surrounded portions 51a in FIG. 1) surrounded by the surrounding portions 51 may each have a quadrangular shape such as a square or rectangular shape, or may have a circular, oval, or another shape in a plan view. The surrounded portions may each have a shape similar to the shape of the light emitters 6 in a plan view. Thus, each surrounding portion 51 is not locally near any points to the anode terminal 61, nor the cathode terminal 62. This reduces short-circuiting between the surrounding portion 51 and the anode terminal 61 or between the surrounding portion 51 and the cathode terminal 62 more effectively.

In the pixel assembly 1, the area (total area) of the connection conductor layer 5 in a plan view may be about 20 to 60% of the area of the second surface 2b. This effectively reduces electrical resistance between the power terminals 4 and the source electrodes 32, thus effectively reducing a drop in the supply voltage fed from the power terminals 4 to the source electrodes 32.

In the pixel assembly 1, the multiple surrounding portions 51 may have a larger total area than the multiple surrounded portions 51a that receive the respective light emitters 6. This structure further increases the area of the connection conductor layer 5, thus further reducing a drop in the supply voltage fed to the source electrodes 32 of the drive transistors 3. The total area of the surrounding portions 51 may be, but not limited to, about more than one time and not more than three times the total area of the surrounded portions 51a. The surrounded portions 51a circular in a plan view can easily have a minimum area and thus may easily have the above structure.

The pixel assembly 1 may have the structure described below. The connection conductor layer 5 may include through-holes 51h in a planar conductor portion 51e on the second surface 2b to receive the light emitters 6. The surrounding portions 51 may be portions of the planar conductor portion 51e other than the through-holes 51h, and the surrounding portions 51 may have a larger area than the openings of the through-holes 51h. This structure further increases the area of the connection conductor layer 5, thus further reducing a drop in the supply voltage fed to the source electrodes 32 of the drive transistors 3.

The power terminals 4 may include multiple first power terminals 41 and multiple second power terminals 42. The first power terminals 41 and the second power terminals 42 may be distributed on a peripheral portion of the second surface 2b or on a peripheral portion of the third surface 7a. This structure with the power terminals 4 near the connection conductor layer 5 effectively reduces a drop in the supply voltage fed from the power terminals 4 to the source electrodes 32.

The connection conductor layer 5 and the light emitters 6 may be at the same height. The height herein refers to a position in the thickness direction of the insulating substrate 2. The height of the connection conductor layer 5 may be the height of the surface of the insulating layer on which the surrounding portions 51 are located. The height of the light emitters 6 may be the height of the surface of the insulating layer on which the anode electrode wires 25 and the cathode electrode wires 26 are located. The connection conductor layer 5, the anode electrode wires 25, and the cathode electrode wires 26 at the same height can be formed at the same time. This facilitates manufacture of the pixel assembly 1. The structure with no steps between the connection conductor layer 5, the anode electrode wires 25, and the cathode electrode wires 26 in the height direction allows light to be emitted from the light emitters 6 without being obstructed by the connection conductor layer 5.

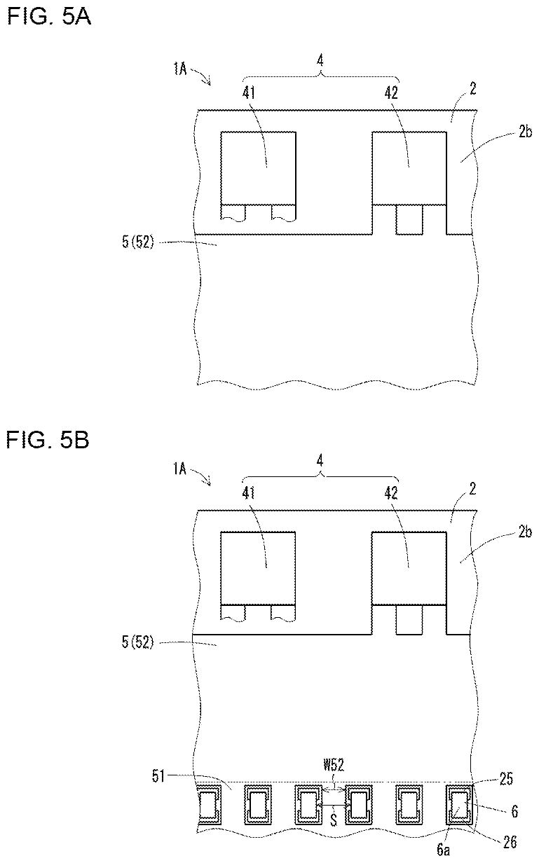

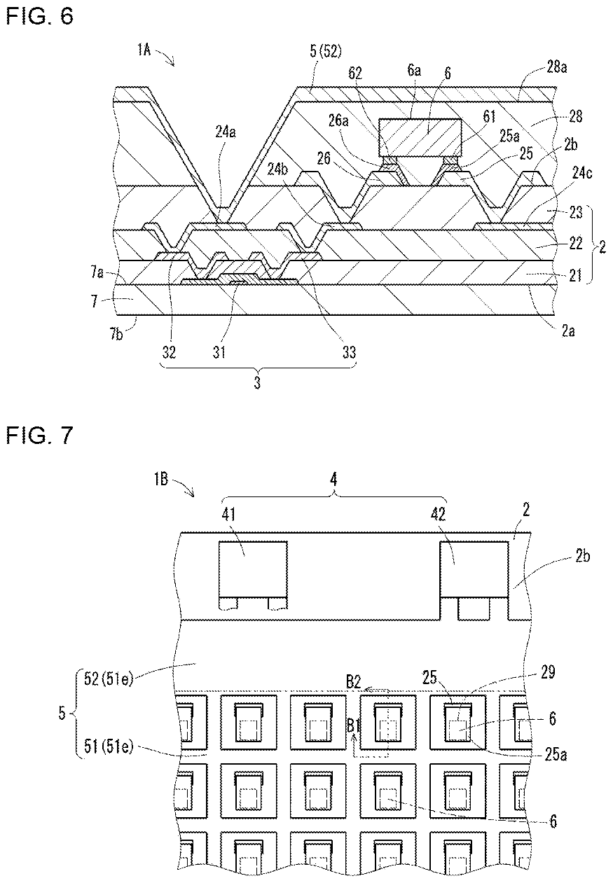

A pixel assembly according to another embodiment of the present disclosure will now be described. FIGS. 5A and 5B are plan views of a pixel assembly according to another embodiment of the present disclosure. FIG. 6 is a cross-sectional view of the pixel assembly according to the other embodiment of the present disclosure. The plan views of FIGS. 5A and 5B correspond to the plan view in FIG. 1. The cross-sectional view of FIG. 6 corresponds to the cross-sectional view in FIG. 2.

In the present embodiment, a pixel assembly 1A basically has the same or similar structure as the pixel assembly 1 in the embodiment described above except for the structures of the connection conductor layer 5 and the light emitters 6. Like reference numerals denote the same or similar components as those of the pixel assembly 1. Such components will not be described.

As illustrated in FIG. 5A, in the pixel assembly IA in the present embodiment, the connection conductor layer 5 that connects the source electrodes 32 of the drive transistors 3 to the power terminals 4 includes a planar portion 52 located on the second surface 2b. The planar portion 52 and the light emitters 6 may be at the same height, or may be at different heights. The height of the planar portion 52 may be the height of the surface of the insulating layer on which the planar portion 52 is located.

As illustrated in, for example, FIG. 5B, the planar portion 52 may include a mesh conductor layer portion. The mesh conductor layer portion may include conductor layer strips surrounding the multiple light emitters 6 individually. In other words, the mesh conductor layer portion may have the same or similar structure as the surrounding portions 51. Each conductor layer strip in the mesh conductor layer portion may have a width W52 of about 60 to 80% of the space S between adjacent light emitters 6. This effectively reduces the electrical resistance of the connection conductor layer 5, thus reducing a drop in the supply voltage fed from the power terminals 4 to the source electrodes 32 in a planar direction along the second surface 2b. This reduces uneven color or uneven luminance in display images.

The planar portion 52 may have an area of at least a half of the area of the second surface 2b. This structure further increases the area of the connection conductor layer 5, thus further reducing a drop in the supply voltage fed to the source electrodes 32 of the drive transistors 3. The area of the planar portion 52 may be, but not limited to, about 50 to 90% inclusive of the area of the second surface 2b.

As illustrated in, for example, FIG. 5A, the planar portion 52 may be located on a peripheral portion of the second surface 2b. This effectively reduces the electrical resistance of the connection conductor layer 5. In particular, this effectively reduces electrical resistance between the power terminal 4 and the connection conductor layer 5. This thus reduces a drop in the supply voltage fed from the power terminals 4 to the source electrodes 32 in a planar direction along the second surface 2b. This reduces uneven color or uneven luminance in display images.

When the insulating substrate 2 is a quadrangular plate, the planar portion 52 may be located near two opposite sides of the second surface 2b in a plan view. This increases the area of the connection conductor layer 5 to effectively reduce the electrical resistance of the connection conductor layer 5, thus effectively reducing a drop in the supply voltage fed from the power terminals 4 to the source electrodes 32 in a planar direction along the second surface 2b. This effectively reduces uneven color or uneven luminance in display images. In this structure, the planar portion 52 may also be located continuously near the four sides of the second surface 2b in a plan view. This structure further increases the area of the connection conductor layer 5, thus more effectively reducing the electrical resistance of the connection conductor layer 5.

As illustrated in, for example, FIGS. 5A and 6, the planar portion 52 may be located across substantially the entire area of the second surface 2b. The pixel assembly 1A may include a transparent insulating layer 28 covering substantially the entire second surface 2b. The planar portion 52 may be located across substantially the entire area of a front surface (upper surface) 28a of the transparent insulating layer 28. This more effectively reduces the electrical resistance of the connection conductor layer 5, thus more effectively reducing a drop in the supply voltage fed from the power terminals 4 to the source electrodes 32 in a planar direction along the second surface 2b. This effectively reduces uneven color or uneven luminance in display images.

The transparent insulating layer 28 may be, for example, an organic insulating layer of silicon oxide (SiO₂), silicon nitride (Si₃N₄), or other materials, or an organic insulating layer of an acrylic resin, a polyimide resin, a polycarbonate resin, or other materials. The connection conductor layer 5 may be a transparent conductive layer of, for example, ITO or IZO.

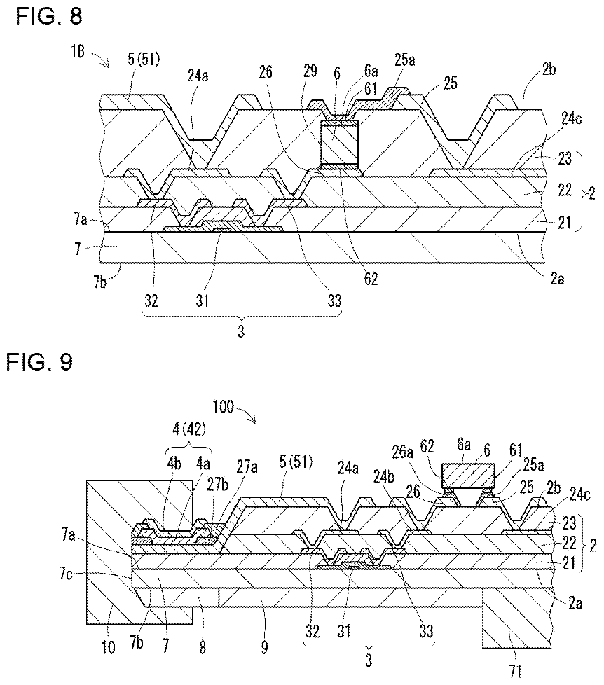

A pixel assembly according to still another embodiment of the present disclosure will now be described. FIG. 7 is a plan view of a pixel assembly according to still another embodiment of the present disclosure. FIG. 8 is a cross-sectional view taken along line B1-B2 in FIG. 7. The plan view of FIG. 7 corresponds to the plan views of FIGS. 1, 5A, and 5B.

In the present embodiment, a pixel assembly 1B basically has the same or similar structure as the pixel assembly 1 in the embodiment described above except for the structures of the light emitters 6 and the cathode electrode wires 26. Like reference numerals denote the same or similar components as those of the pixel assembly 1. Such components will not be described.

In the pixel assembly 1B in the present embodiment, each light emitter 6 is located in a recess 29 in the insulating substrate 2, as illustrated in FIG. 8. The recesses 29 are open on the second surface 2b of the insulating substrate 2 and are recessed in the thickness direction of the insulating substrate 2. The recesses 29 may be through-holes extending through the insulating layer 23 in the thickness direction.

The light emitters 6 may be vertical LEDs. In this case, the light emitters 6 may be located in the recesses 29 with their light-emitting surfaces 6a facing the openings of the recesses 29. The anode terminals 61 of the light emitters 6 may be connected to the anode electrode wires 25 with the transparent conductive layer 25a on the second surface 2b in between. The cathode terminals 62 of the light emitters 6 may be directly connected to the cathode electrode wires 26 between the insulating layer 22 and the insulating layer 23. The light emitters 6 may have their side surfaces in contact with the inner surfaces of the recesses 29. This efficiently dissipates heat generated by the light emitters 6 in operation into the insulating substrate 2.

The connection conductor layer 5 is located on the second surface 2b. The connection conductor layer 5 includes at least one of the surrounding portion 51 or the planar portion 52. The surrounding portion 51 may have the same or similar structure as the surrounding portion 51 of the pixel assembly 1. The planar portion 52 may have the same or similar structure as the planar portion 52 of the pixel assembly 1A. This increases the area of the connection conductor layer 5 to reduce the electrical resistance of the connection conductor layer 5, thus reducing a drop in the supply voltage fed from the power terminals 4 to the source electrodes 32 in a planar direction along the second surface 2b. This reduces uneven color or uneven luminance in display images. In FIG. 7, the planar portion 52 is located on a peripheral portion of the second surface 2b, but the planar portion 52 may be located on, for example, a portion inward from the peripheral portion of the second surface 2b. As illustrated in, for example, FIG. 6, the planar portion 52 may also be located across substantially the entire area of the second surface 2b.

As illustrated in FIG. 7, at least one of the surrounding portion 51 or the planar portion 52 as the conductor portion 51e may have an area being at least a half area of the second surface 2b. This structure further increases the area of the connection conductor layer 5, thus further reducing a drop in the supply voltage fed to the source electrodes 32 of the drive transistors 3. The area of the conductor portion 51e may be, but not limited to, about 50 to 90% inclusive of the area of the second surface 2b.

In a structure including the surrounding portion 51 and the planar portion 52, the planar portion 52 may have an area larger than or equal to the area of the surrounding portion 51, or may have an area larger than the area of the surrounding portion 51. These structures allow the area of the connection conductor layer 5 to be increased easily. In other words, increasing the area of the surrounding portion 51 including the surrounded portions 51a does not largely increase the area of the connection conductor layer 5. In contrast, increasing the area of the planar portion 52 can largely increase the area of the connection conductor layer 5 by directly increasing the area of the connection conductor layer 5. The area of the planar portion 52 may be, but not limited to, about one time or more and two times or less the area of the surrounding portion 51.

In a structure including the surrounding portion 51 and the planar portion 52, the thickness of the planar portion 52 may be larger than or equal to the thickness of the surrounding portion 51, or the thickness of the planar portion 52 may be larger than the thickness of the surrounding portion 51. These structures allow the thickness of the connection conductor layer 5 to be increased easily. Increasing the thickness of the connection conductor layer 5 reduces the electrical resistance of the connection conductor layer 5. Increasing the thickness of the surrounding portion 51 including the surrounded portions 51a does not largely increase the thickness of the connection conductor layer 5. In contrast, increasing the thickness of the planar portion 52 can largely increase the thickness of the connection conductor layer 5 by directly increasing the thickness of the connection conductor layer 5. The thickness of the planar portion 52 may be, but not limited to, about one time or more and five times or less the thickness of the surrounding portion 51.

A display device according to an embodiment of the present disclosure will now be described. FIG. 9 is a cross-sectional view of a display device according to an embodiment of the present disclosure. The cross-sectional view of FIG. 9 corresponds to the cross-sectional view of FIG. 2.

In the present embodiment, a display device 100 includes the pixel assembly 1 and the substrate 7. FIG. 9 illustrates the display device 100 including the pixel assembly 1. The display device 100 may include at least one of the pixel assembly 1, 1A, or 1B.

The pixel assembly 1 is on the third surface 7a of the substrate 7. The pixel assembly 1 is located with the first surface 2a of the insulating substrate 2 facing the third surface 7a. As illustrated in, for example, FIG. 9, the power terminals 4 may be located on a peripheral portion of the third surface (also referred to as a front surface or a display surface) 7a. In the example in FIG. 9, the power terminal 4 includes two metal layers 4a and 4b. As illustrated in, for example, FIG. 9, an insulating layer 27a may be located on a portion between the metal layers 4a and 4b, and an insulating layer 27b may be located on a portion between the metal layer 4a and the connection conductor layer 5.

The substrate 7 includes a drive 71 that drives the pixel assembly 1. The drive 71 is located on a fourth surface (also referred to as a back surface or a non-display surface) 7b of the substrate 7. The drive 71 may be connected to an external power supply. The drive 71 may generate a first power supply voltage VDD and a second power supply voltage VSS based on the power fed from the external power supply, and feed the generated first power supply voltage VDD and the second power supply voltage VSS to the pixel assembly 1. The drive 71 may be connected to an external circuit. The drive 71 may generate control signals such as an emission control signal and a scanning signal based on image signals and other signals input from the external circuit, and provide the generated control signals to the pixel assembly 1.

The display device 100 includes back power terminals 8 and back wires 9. The back power terminals 8 are located on the fourth surface 7b. The back power terminals 8 may be located on a peripheral portion of the fourth surface 7b. The back power terminals 8 may overlap the power terminals 4 in a plan view. The back wires 9 are located on the fourth surface 7b and connect the drive 71 and the back power terminals 8. The back power terminals 8 may include, for example, layers of Al, Al/Ti, Ti/Al/Ti, Mo, Mo/Al/Mo, MoNd/AlNd/MoNd, Cu, Cr, Ni, or Ag. The back wires 9 may include, for example, layers of Mo/Al/Mo or MoNd/AlNd/MoNd. In the example in FIG. 9, the back power terminals 8 and the back wires 9 each include a single metal layer.

The display device 100 may include side wiring 10. The side wiring 10 is located on the side surfaces 7c of the substrate 7. The side wiring 10 extends to the third surface 7a and to the fourth surface 7b to connect the power terminals 4 and the back power terminals 8. In other words, the side wiring 10 electrically connects the pixel assembly 1 and the drive 71.

Although the pixel assembly 1 and the drive 71 may be connected to feedthrough conductors extending from the third surface 7a to the fourth surface 7b, the side wiring 10 may be used for the connection to allow the display device 100 to reduce or eliminate its frame portion.

The side wiring 10 may include a conductive paste containing conductive particles of, for example, Ag, Cu, Al, or stainless steel, an uncured resin component, an alcohol solvent, and water. The conductive paste may be applied to an intended portion extending from the side surface 7c to the third surface 7a and to the fourth surface 7b and cured by heating, photocuring using ultraviolet ray irradiation, or a combination of photocuring and heating. The side wiring 10 may also be formed with a thin film formation method such as plating, vapor deposition, or CVD. The side surfaces 7c of the substrate 7 may include grooves formed in advance for the side wiring 10. This allows the conductive paste that forms the side wiring 10 to be easily received in the intended portion on the side surfaces 7c.

This display device 100 including the pixel assembly 1 reduces uneven color or uneven luminance in display images. Thus, the display device 100 can have higher image quality.

The pixel assembly 1 in the display device 100 may include light emitters 6 on protrusions on the second surface 2b of the insulating substrate 2. This structure allows light to be emitted from the light emitters 6 without being obstructed by surrounding components. This also reduces the likelihood of a transfer plate hitting the second surface 2b when the light emitters 6 are transferred onto the second surface 2b of the insulating substrate 2, thus improving the manufacturing yield.

In the pixel assembly according to one or more embodiments of the present disclosure, the connection conductor layer has an increased area, reducing a drop in the supply voltage fed to the source electrodes of the drive transistors. This can reduce uneven colors or uneven luminance in the display images and improve the image quality of the display device. In one or more embodiments of the present disclosure, the display device including the above pixel assembly reduces uneven color or uneven luminance in display images and thus improves the image quality of the display device.

The present disclosure may be implemented in forms 1 to 17 described below.

(1) A pixel assembly, comprising:
an insulating substrate including a first surface and a second surface on an opposite side to the first surface:
a drive transistor in the insulating substrate or on the first surface, the drive transistor including a source electrode and a drain electrode:
a power feeder connectable to an external power supply:
a connection conductor layer on the insulating substrate, the connection conductor layer connecting the source electrode to the power feeder; and
a light emitter on the second surface, the light emitter being electrically connected to the drain electrode,
wherein the connection conductor layer includes a surrounding portion surrounding the light emitter in a plan view on the second surface.

(2) The pixel assembly according to (1), wherein
the pixel assembly comprises a plurality of the light emitters and a plurality of the surrounding portions surrounding respective light emitters of the plurality of light emitters, and
the plurality of the surrounding portions connects to one another.

(3) The pixel assembly according to (2), wherein
the plurality of the surrounding portions has a larger area than a plurality of surrounded portions receiving the respective light emitters of the plurality of light emitters.

(4) The pixel assembly according to (1), wherein
the connection conductor layer includes a through-hole in a planar conductor portion on the second surface, the through-hole receiving the light emitter, and
the surrounding portion is a portion of the planar conductor portion other than the through-hole, the surrounding portion having a larger area than an opening of the through-hole.

(5) The pixel assembly according to any one of (1) to (4), wherein
the drive transistor is a p-channel thin-film transistor,
the power feeder includes a first power feeder to which a first power supply voltage is applied and a second power feeder to which a second power supply voltage lower than the first power supply voltage is applied, and
the source electrode is connected to the first power feeder.

(6) The pixel assembly according to any one of (1) to (4), wherein
the drive transistor is an n-channel thin-film transistor,
the power feeder includes a first power feeder to which a first power supply voltage is applied and a second power feeder to which a second power supply voltage lower than the first power supply voltage is applied, and
the source electrode is connected to the second power feeder.

(7) A pixel assembly, comprising:
an insulating substrate including a first surface and a second surface on an opposite side to the first surface:
a drive transistor in the insulating substrate or on the first surface, the drive transistor including a source electrode and a drain electrode:
a power feeder connectable to an external power supply:
a connection conductor layer on the insulating substrate, the connection conductor layer connecting the source electrode to the power feeder; and
a light emitter on the second surface, the light emitter being electrically connected to the drain electrode,
wherein the connection conductor layer includes a planar portion on the second surface.

(8) The pixel assembly according to (7), wherein
the planar portion has an area of at least a half of an area of the second surface.

(9) The pixel assembly according to (8), wherein
the connection conductor layer is at a height different from a height at which the light emitter is located on the second surface.

(10) The pixel assembly according to any one of (7) to (9), wherein
the drive transistor is a p-channel thin-film transistor,
the power feeder includes a first power feeder to which a first power supply voltage is applied and a second power feeder to which a second power supply voltage lower than the first power supply voltage is applied, and
the source electrode is connected to the first power feeder.

(11) The pixel assembly according to any one of (7) to (9), wherein
the drive transistor is an n-channel thin-film transistor,
the power feeder includes a first power feeder to which a first power supply voltage is applied and a second power feeder to which a second power supply voltage lower than the first power supply voltage is applied, and
the source electrode is connected to the second power feeder. (12) A pixel assembly, comprising:
an insulating substrate including a first surface and a second surface on an opposite side to the first surface, the insulating substrate including a recess on the second surface:
a drive transistor in the insulating substrate or on the first surface, the drive transistor including a source electrode and a drain electrode:
a power feeder connectable to an external power supply:
a connection conductor layer on the insulating substrate, the connection conductor layer connecting the source electrode to the power feeder; and
a light emitter in the recess, the light emitter being electrically connected to the drain electrode,
wherein the connection conductor layer includes at least one of a surrounding portion surrounding the light emitter in a plan view or a planar portion on the second surface.

(13) The pixel assembly according to (12), wherein
the at least one of the surrounding portion or the planar portion is a conductor portion, the conductor portion having an area being at least a half area of the second surface.

(14) The pixel assembly according to (12) or (13), wherein
the drive transistor is a p-channel thin-film transistor,
the power feeder includes a first power feeder to which a first power supply voltage is applied and a second power feeder to which a second power supply voltage lower than the first power supply voltage is applied, and
the source electrode is connected to the first power feeder.

(15) The pixel assembly according to (12) or (13), wherein
the drive transistor is an n-channel thin-film transistor,
the power feeder includes a first power feeder to which a first power supply voltage is applied and a second power feeder to which a second power supply voltage lower than the first power supply voltage is applied, and
the source electrode is connected to the second power feeder.

(16) A display device, comprising:
the pixel assembly according to any one of (1) to (15); and
a substrate including one main surface receiving the pixel assembly and another main surface receiving a drive configured to drive the light emitter, the other main surface being opposite to the one main surface.

(17) The display device according to (16), wherein
the substrate includes a side surface connecting the one main surface and the other main surface, and the display device comprises side wiring electrically connecting the pixel assembly and the drive on the side surface.

Although the embodiments of the present disclosure have been described in detail, the present disclosure is not limited to the embodiments described above, and may be changed or varied in various manners without departing from the spirit and scope of the present disclosure. The components described in the above embodiments may be entirely or partially combined as appropriate unless any contradiction arises.

### INDUSTRIAL APPLICABILITY

The pixel assembly and the display device according to one or more embodiments of the present disclosure may be used for various electronic devices. Such electronic devices include lighting apparatus, automobile route guidance systems (car navigation systems), ship route guidance systems, aircraft route guidance systems, indicators for instruments in vehicles such as automobiles, instrument panels, smartphones, mobile phones, tablets, personal digital assistants (PDAs), video cameras, digital still cameras, electronic organizers, electronic books, electronic dictionaries, personal computers, copiers, terminals for game devices, television sets, product display tags, price display tags, programmable display devices for industrial use, car audio systems, digital audio players, facsimile machines, printers, automatic teller machines (ATMs), vending machines, medical display devices, digital display watches, smartwatches, guidance display devices installed in stations or airports, and signage (digital signage) for advertisement.

### REFERENCE SIGNS

1, 1A, 1B pixel assembly
100 display device
2 insulating substrate
2a first surface (one main surface)
2b second surface (the other main surface)
21, 22, 23 insulating layer
24 internal wire
24a, 24b, 24c internal wire
25 anode electrode wire
25a transparent conductive layer
26 cathode electrode wire
26a transparent conductive layer
27a, 27b insulating layer
28 transparent insulating layer
29 recess
3 drive transistor
31 gate electrode
32 source electrode
33 drain electrode
4 power terminal
4a, 4b metal layer
41 first power terminal
42 second power terminal
5 connection conductor layer
51 surrounding portion
51a surrounded portion
51e conductor portion
51h through-hole
52 planar portion
6 light emitter
6a light-emitting surface
61 anode terminal
62 cathode terminal
7 substrate
7a third surface (one main surface)
7b fourth surface (the other main surface)
7c fifth surface (side surface)
71 drive
8 back power terminal
9 back wire
10 side wiring

1. A pixel assembly, comprising:
an insulating substrate including a first surface and a second surface on an opposite side to the first surface;
a drive transistor in the insulating substrate or on the first surface, the drive transistor including a source electrode and a drain electrode;
a power feeder connectable to an external power supply;
a connection conductor layer on the insulating substrate, the connection conductor layer connecting the source electrode to the power feeder; and
a light emitter on the second surface, the light emitter being electrically connected to the drain electrode,
wherein the connection conductor layer includes a surrounding portion surrounding the light emitter in a plan view on the second surface.

2. The pixel assembly according to claim 1, wherein
the pixel assembly comprises a plurality of the light emitters and a plurality of the surrounding portions surrounding respective light emitters of the plurality of the light emitters, and
the plurality of the surrounding portions connects to one another.

3. The pixel assembly according to claim 2, wherein
the plurality of the surrounding portions has a larger area than a plurality of surrounded portions receiving the respective light emitters of the plurality of light emitters.

4. The pixel assembly according to claim 1, wherein
the connection conductor layer includes a through-hole in a planar conductor portion on the second surface, the through-hole receiving the light emitter, and
the surrounding portion is a portion of the planar conductor portion other than the through-hole, the surrounding portion having a larger area than an opening of the through-hole.

5. The pixel assembly according to claim 1, wherein
the drive transistor is a p-channel thin-film transistor,
the power feeder includes a first power feeder to which a first power supply voltage is applied and a second power feeder to which a second power supply voltage lower than the first power supply voltage is applied, and
the source electrode is connected to the first power feeder.

6. The pixel assembly according to claim 1, wherein
the drive transistor is an n-channel thin-film transistor,
the power feeder includes a first power feeder to which a first power supply voltage is applied and a second power feeder to which a second power supply voltage lower than the first power supply voltage is applied, and
the source electrode is connected to the second power feeder.

7. A pixel assembly, comprising:
an insulating substrate including a first surface and a second surface on an opposite side to the first surface;
a drive transistor in the insulating substrate or on the first surface, the drive transistor including a source electrode and a drain electrode;
a power feeder connectable to an external power supply;
a connection conductor layer on the insulating substrate, the connection conductor layer connecting the source electrode to the power feeder; and
a light emitter on the second surface, the light emitter electrically connected to the drain electrode,
wherein the connection conductor layer includes a planar portion on the second surface.

8. The pixel assembly according to claim 7, wherein
the planar portion has an area of at least a half of an area of the second surface.

9. The pixel assembly according to claim 8, wherein
the connection conductor layer is at a height different from a height at which the light emitter is located on the second surface.

10. The pixel assembly according to claim 7, wherein
the drive transistor is a p-channel thin-film transistor,
the power feeder includes a first power feeder to which a first power supply voltage is applied and a second power feeder to which a second power supply voltage lower than the first power supply voltage is applied, and
the source electrode is connected to the first power feeder.

11. The pixel assembly according to claim 7, wherein
the drive transistor is an n-channel thin-film transistor,
the power feeder includes a first power feeder to which a first power supply voltage is applied and a second power feeder to which a second power supply voltage lower than the first power supply voltage is applied, and
the source electrode is connected to the second power feeder.

12. A pixel assembly, comprising:
an insulating substrate including a first surface and a second surface on an opposite side to the first surface, the insulating substrate including a recess on the second surface;
a drive transistor in the insulating substrate or on the first surface, the drive transistor including a source electrode and a drain electrode;
a power feeder connectable to an external power supply;
a connection conductor layer on the insulating substrate, the connection conductor layer connecting the source electrode to the power feeder; and
a light emitter in the recess, the light emitter being electrically connected to the drain electrode,
wherein the connection conductor layer includes at least one of a surrounding portion surrounding the light emitter in a plan view or a planar portion on the second surface.

13. The pixel assembly according to claim 12, wherein
the at least one of the surrounding portion or the planar portion is a conductor portion, the conductor portion having an area being at least a half area of the second surface.

14. The pixel assembly according to claim 12, wherein
the drive transistor is a p-channel thin-film transistor,
the power feeder includes a first power feeder to which a first power supply voltage is applied and a second power feeder to which a second power supply voltage lower than the first power supply voltage is applied, and
the source electrode is connected to the first power feeder.

15. The pixel assembly according to claim 12, wherein
the drive transistor is an n-channel thin-film transistor,
the power feeder includes a first power feeder to which a first power supply voltage is applied and a second power feeder to which a second power supply voltage lower than the first power supply voltage is applied, and
the source electrode is connected to the second power feeder.

16. A display device, comprising:
the pixel assembly according to claim 1; and
a substrate including one main surface receiving the pixel assembly and another main surface receiving a drive configured to drive the light emitter, the other main surface being on an opposite side to the one main surface.

17. The display device according to claim 16, wherein
the substrate includes a side surface connecting the one main surface and the other main surface, and the display device comprises side wiring electrically connecting the pixel assembly and the drive on the side surface.
